(19) United States
(12) Patent Application Publication
(10) Pub. No.: US 2017/0010320 A1
(43) Pub. Date: Jan. 12, 2017

(54) REDUCING TEST TIME AND SYSTEM-ON-CHIP (SOC) AREA REDUCTION USING SIMULTANEOUS CLOCK CAPTURE BASED ON VOLTAGE SENSOR INPUT

(71) Applicant: QUALCOMM Incorporated, San Diego, CA (US)

(72) Inventors: Dipti Ranjan Pal, San Diego, CA (US); Kumar Kanti Ghosh, San Diego, CA (US)

(21) Appl. No.: 14/796,185

(22) Filed: Jul. 10, 2015

(51) Int. Cl. G01R 31/28

(52) U.S. Cl. CPC G01R 31/2834

(57) ABSTRACT

A method and apparatus for testing an electronic component is provided. The method begins when a design-for-test (DFT) mode is entered and at least one sensor is enabled. Sensor results are monitored and determine the number of cores or capture domains that may be tested simultaneously. The sensors include a voltage and temperature sensor, and either or both sensors may be enabled during testing. Maximum and minimum voltage levels for each capture domain determine at what value a voltage drop occurs. The number of cores selected minimizes a voltage drop across the electronic component. Maximum and minimum temperatures across the multiple cores of the electronic component determine the number of clocks that may be operated simultaneously during testing. An apparatus includes an electronic device to be tested, test sensors on the electronic device, and an interface to a test fixture.

### FIELD

The present disclosure relates generally to wireless communication systems, and more particularly to a method and apparatus for reducing test time and area needed by a system-on-chip (SoC) device using simultaneous at-speed capture of the clock domains on the device.

### BACKGROUND

Wireless communication devices have become smaller and more powerful as well as more capable. Increasingly users rely on wireless communication devices for mobile phone use as well as email and Internet access. At the same time, devices have become smaller in size. Devices such as cellular telephones, personal digital assistants (PDAs), laptop computers, and other similar devices provide reliable service with expanded coverage areas. Such devices may be referred to as mobile stations, stations, access terminals, user terminals, subscriber units, user equipments, and similar terms. These wireless devices rely on SoCs to provide much of the functionality desired by users.

SoCs are tested prior to assembly in wireless devices to ensure that the chip functions as desired within specified operating parameters. Testing SoCs may rely on design for test (DFT) which is a process that incorporates rules and techniques for testing into the design of the chip to facilitate testing prior to delivery. DFT may be used to manage test complexity, minimize development time and reduce manufacturing costs. Testing involves two major aspects: control and observation. When testing any system or device it is necessary to put the system into a known state, supply known input data (the test data) and then observe the system or chip to ascertain if it performs as designed. Other integrated circuit (IC) devices require similar testing, and embodiments described herein also apply to testing electronic chips, or ICs.

Designers and manufacturers usually test various functions to validate the design. Often manufacturing engineers and customer engineers subject a chip design to a variety of test criteria to determine if the ideas in the design work in practice. This validation is especially important for SoCs which involve a unique set of problems that challenge test procedures. Although high density modern circuits, higher device speeds, surface-mount packaging, and complex board interconnect technologies have had a positive influence on state-of-the-art electronic systems, these factors have also greatly increased test complexity and cost. The cost for detecting and identifying faults using traditional test methods increases by an order of magnitude as circuit complexity increases. These increased costs and development time may delay product introduction and reduce time-to-market windows. DFT provides a system level approach to testing that mitigates these factors.

As part of the testing process standardized test interfaces have been developed, which facilitate SoC testing. For chip devices, the standard is defined by the Institute of Electrical and Electronics Engineers (IEEE) Standard 1149.1-1990 provides through the Joint Test Action Group (JTAG) and interface for testing chip-level devices. Every IEEE Std. 1149.1 compatible chip design provides four additional pins, two for control and one each for input and output serial data.

Using the JTAG interface a SoC will be tested to ensure that all internal clocks perform as specified. As devices become more complex with more functions provided within one chip, additional clocks are used to synchronize and control functions performed by the multiple cores within the device. Testing all of the clocks within a SoC requires significant time. This testing time may be increased due to a variety of faults that may be found and also because testing multiple clocks simultaneously may cause significant heat to be generated in the device. Additionally, when multiple clocks are tested at the same time the voltage may drop, causing noise or other faults to be generated. When these faults are caused by the multiple test clocks running there is no way to determine if the fault is inherent in the manufacturing of the chip, or is a false fault created by the testing process. There is a need in the art for a method and apparatus to test multiple clock speeds without voltage drop or false failures to be generated.

### SUMMARY

Embodiments described herein provide a method for testing an electronic component. The method begins when a design-for-test (DFT) mode is entered. At least one sensor is enabled to operate during the DFT mode. The sensor results are monitored and used to determine the number of cores or capture domains that may be tested simultaneously without adversely affecting the test results. The sensors may be a voltage and temperature sensor, and either or both sensors may be enabled during DFT testing. The voltage sensor is used to determine the maximum and minimum voltage levels for each capture domain. This is used to determine at what value the voltage drop occurs, with the number of cores selected to minimize a voltage drop across the electronic component. The temperature sensor captures the maximum and minimum temperatures across the multiple cores of the electronic component. This result may be used to determine the number of clocks that may be operating simultaneously during testing.

A further embodiment provides an apparatus for testing an electronic component. The apparatus includes an electronic component having multiple cores and multiple capture domains. The apparatus includes test sensors for voltage and temperature on the electronic component that are in communication with the multiple cores and capture domains and an interface to a test fixture.

A still further embodiment provides an apparatus for testing an electronic component. The apparatus includes: means for entering a DFT mode; means for enabling at least one sensor to operate when the electronic component is in the DFT mode; means for monitoring the at least one sensor output results, and means for determining a number of cores or capture domains that may be tested simultaneously based on the at leas one sensor output results.

### BRIEF DESCRIPTION OF THE DRAWINGS

FIG. 1 illustrates a representative electronic chip with multiple clocks, in accordance with embodiments described herein.

FIG. 2 shows a test clock block used for testing electronic chip devices, in accordance with embodiments described herein.

FIG. 3 shows an electronic chip device with voltage sensors enabled during clock testing, in accordance with embodiments described herein.

FIG. 4 illustrates an apparatus for enabling voltage sensors during clock testing, in accordance with embodiments described herein.

FIG. 5 is a flow chart for testing electronic chips using simultaneous at-speed capture using input from voltage sensors, in accordance with embodiments described herein.

FIG. 6 is a flow chart for testing electronic chips using simultaneous at-speed capture using input from temperature sensors, in accordance with embodiments described herein.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, an integrated circuit, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network, such as the Internet, with other systems by way of the signal).

Moreover, various aspects or features described herein may be implemented as a method, apparatus, or article of manufacture using standard programming and/or engineering techniques. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ), and integrated circuits such as read-only memories, programmable read-only memories, and electrically erasable programmable read-only memories.

Various aspects will be presented in terms of systems that may include a number of devices, components, modules, and the like. It is to be understood and appreciated that the various systems may include additional devices, components, modules, etc. and/or may not include all of the devices, components, modules etc. discussed in connection with the figures. A combination of these approaches may also be used.

Other aspects, as well as features and advantages of various aspects, of the present invention will become apparent to those of skill in the art through consideration of the ensuring description, the accompanying drawings and the appended claims.

Testing electronic chips requires planning for testing the chip as the chip is being designed. This may mean integrating testing pins and interfaces into the device so that test signals or built-in self-test (BIST) tests may be performed without probing the chip. This testing uses a test clock to route signals through cores of a chip and recording the results. The test clock circuit includes a core clock circuit, a pad clock circuit, a test clock circuit among others. The core clock circuit generates a core clock signal enabling full speed operation of the core circuitry of the IC during test mode. The pad clock circuit generates a preliminary clock signal suitable for normal operation, and the test clock circuit generates a test clock signal suitable for operating the input/output (I/O) interface logic while in test mode.

This testing is usually carried out by inserting the IC to be tested, or device under test (DUT) into a test fixture which simulates and monitors the I/O signals of the chip or IC to determine if the IC is functioning properly. For a microprocessor, the tester may generate and monitor all of the I/O signals needed to interface the IC to other components it must operate in conjunction with. For most IC devices currently in use, the frequency at which the microprocessor operates is a multiple of the frequency of the bus clock frequency provided by the tester. Provisions may need to be made when designing the IC to enable the core logic to operate at full speed during testing. Typically this involves providing clock frequency ratio values that are enabled only during testing. A multiplier may be used to increase the internal clock speed for testing purposes. This may result in multiple clocks running simultaneously.

During testing test data is scanned in to simulate internal system nodes within the IC while the IC is loaded in the test system. During the same scan, the previous condition of each node in the scan chain is scanned out. Samples are taken on the rising edge of the test clock. Testing mode selection and test data inspect values are sampled on the rising edge of the test clock, and the test data output data is sampled on the falling edge of the clock.

Testing is designed to handle three specific types of faults: stuck at fault test, transition delay fault, and path delay fault. A fault is a design failure or flaw that causes an incorrect response to input stimuli. When the test data is output, the values do not match the values of a correctly functioning IC or other electronic device. The stuck at fault test represents a failure model where a gate pin is stuck either open or closed. A closed gate indicates a short. A fault simulator uses fault models to represent a node shorted to ground, compared with a fault free circuit. An open gate is shorted to power. By faulting all of the nodes in the circuit the fault simulator produces the test pattern fault coverage.

The stuck at fault test is run using a slow speed clock and the entire IC is tested. In this test, both shifting in of test values and capture, or shifting out test values, use a slow pad clock. During the stuck at fault test all of the scan chains toggle at the same time irrespective of clock domains, voltage domains, or power domains. Scan chains allow every flip-flop in an IC to be monitored for particular parameters. For many SoCs the typical speed of the slow pad clock ranges from 25 MHz to 100 MHz, depending on the specific test fixture.

Transition delay faults cause errors in the functioning of a circuit based on its timing. These faults are caused by the finite rise and fall times of the signals in the gates and also by the propagation delay of interconnects between the gates. Circuit timing should be carefully evaluated to avoid this type of error. Transition delay testing may also be used to determine the proper clock frequency of the circuit for correct functionality. Transition delay faults are caused by the finite time it takes for a gate input to show up at the output. If the signals are not given time to settle, a transition delay fault may appear. A challenge in testing is distinguishing between a delay fault, where the output yields the correct result, and an actual fault in the circuit. Tests may be developed to distinguish between slow to rise and slow to fall situations.

Transition delay fault testing use a slow pad clock for shifting values into and out of the flip-flops in the circuit. Capture uses a high speed clock. Each clock domain is tested separately, and may use the same timing. Transition delay tests are performed for all the logic on the chip.

The path delay fault test looks at the longest path in the circuit and determine the effect on circuit timing. The longest path is typically determined based on the results of static timing analysis of the chip. In static timing analysis the expected timing of a digital circuit is determined without simulation. Once the longest path or critical path has been determined, path delay fault testing may be performed. In path delay fault testing shifting data is performed using a slow pad clock while data capture uses a high speed clock. Each clock domain is tested separately.

A typical SoC has a core using at least one clock, and many have multiple clocks. Multiple clocks may be used in an SoC to limit the power used by the chip. The multiple clocks as well as every core on the chip use a different frequency. Most of the clocks are gated and are only un-gated when the clock is being used. As a result, at any given time the majority of flip-flops on the SoC are either clock gates or the domains are power collapsed during actual functional operation.

The power delivery network supplies power to all of the logic gates on the SoC or chip. Testing is a unique situation for the SoC, as during DFT mode operation all of the clock domains are on and during shift operations all of the flip-flops are toggling at their respective functional frequencies. Only during testing are all cores of the SoC on as most of the clocks are gated in normal operation and are only un-gated when in use. This operation results in increased heat being generated, and this heat affects SoC or chip operation. This thermal loading may cause false failures due to the heat generated. To cope with the heat loading it may be necessary to lower the shift frequency and stagger to capture of the domains to isolate these false failures. This causes increased testing time.

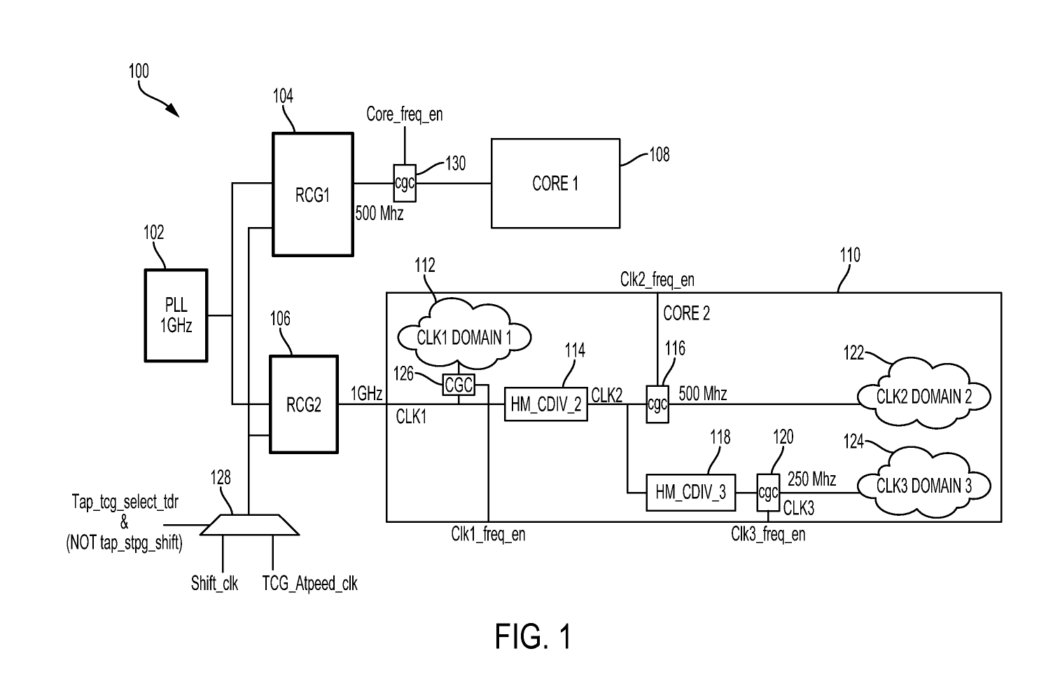

FIG. 1 is a block diagram of a typical SoC. The assembly 100 includes a phase locked loop (PLL) 102 which is connected to a first divider 104 and a second divider 106. First divider 104 is connected to a clock gate 130 and a first processor core 108. Second divider 106 is connected to a second processor core 110 having three clock domains. Clock domain 112 is connected to clock generation circuit 126. A second clock source 114 is also connected to clock generation circuit 126 and also to internal clock generator 116. Second clock source 114 is also connected to third clock source 120. Internal clock generator 116 is connected to second clock domain 122. Third clock source 120 is connected to third clock domain 124. PLL 102, first divider 104, and second divider 106 are also connected to a 2:1 multiplexer 128.

The three clocks sources and domains shown in FIG. 1 are tested using the stuck at fault test, transition delay fault test, and path delay fault testing described above.

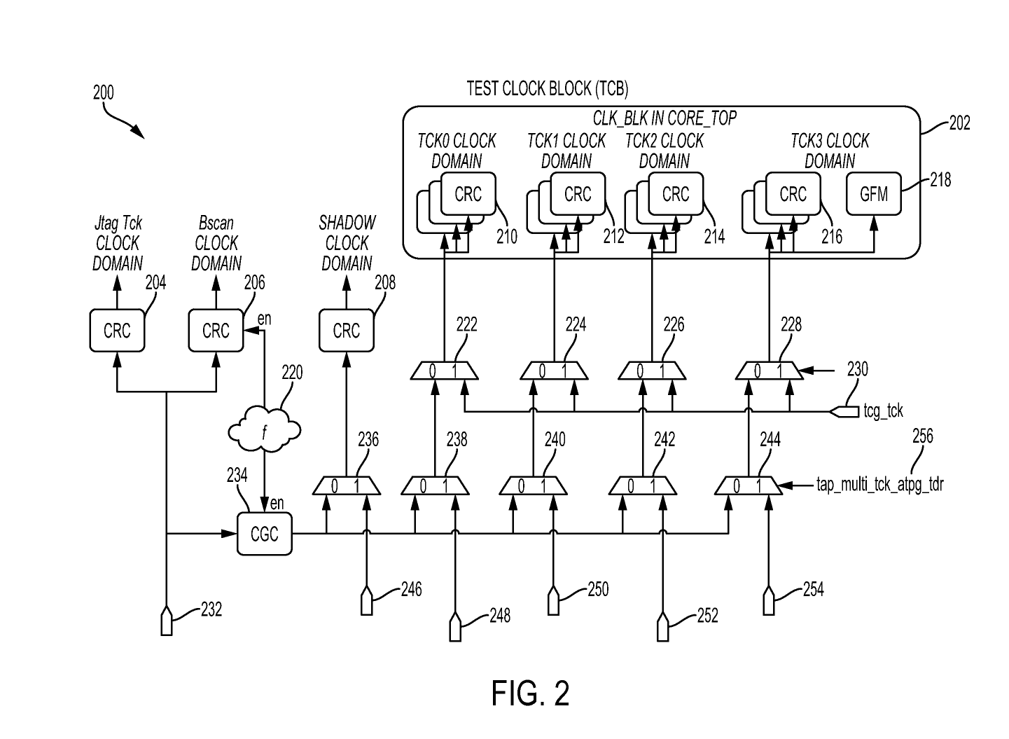

FIG. 2 illustrates a test clock circuit that may be used to test an SoC such as that shown in FIG. 1. The assembly 200, includes a test clock block 202. Test clock block 202 includes a first clock domain 210 (TCK0), a second clock domain 212 (TCK1), a third clock domain 214 (TCK2), and fourth clock domain (TCK3) 216. Each clock domain 210, 212, 214, and 216 includes multiple cyclic redundancy checks (CRC). In addition, fourth clock domain 216 includes multiple CRCs connected to multiple generator fault modules 218. For each clock domain 210, 212, 214, and 216 the outputs of the multiple CRCs are connected to multiplexers 222, 224, 226, and 228.

The test clock circuit also includes interfaces with a JTAG interface. The JTAG interface includes a JTAG clock domain 204 that includes a CRC. The JTAG clock domain 204 is connected to boundary scan clock domain 206. Boundary scan clock domain 206 is also connected to a CRC and the output of this CRC is connected to the output of the CRC connected to the JTAG clock domain 204. Both the JTAG clock domain 204 and boundary scan clock domain 206 output results on JTAG output pin 232.

Boundary scan clock domain 206 through the connection with a CRC is also in communication with function cloud 220. Function cloud 220 provides the means for loading desired test programs and functions into the JTAG and boundary scan clock domains. The function cloud 220 is also in communication with CRC 234, which also connects to the interconnection of the JTAG clock domain 204 and boundary scan chain 206 output line.

Shadow clock domain 208 through its CRC is also connected to a multiplexer 236. The multiplexer 236 also received and input from CRC 234 and JTAG test clock input pin 246. Multiplexer 222 is connected to a further multiplexer 238. Further multiplexer 238 also receives input from CGC 234 and JTAG test clock pin 248. Multiplexer 224 is also connected to further multiplexer 240. Further multiplexer 240 also receives input from JTAG test clock input pin 250. Similarly, multiplexer 226 is also connected to further multiplexer 242, which receives input from JTAG test clock input pin 252. Multiplexer 228 is also connected to further multiplexer 244, which receives input from JTAG test clock input pin 254. Multiplexers 222, 224, 226, and 228 each also receive an input form JTAG memory test clock input pin 230. Multiplexer 244 receives an input from control signaling pin 256.

In operation, the test clock circuit of FIG. 2 provides support for fifteen independent test clock pads for use in DFT operation. The number of independent test clock pads may increase the cost of the package, as these test clock pads must be designed and fabricated into every chip. Furthermore, in use, the test clock circuit provides for clock edges to be skewed from one another, to avoid simultaneous switching of all the flip-flops in the circuit. DFT operation in this manner results in increased test time. When running transition delay fault and path delay fault testing fewer clock domains may be captured to reduce voltage or IR drop. This also results in increased test time.

The voltage drop means that the voltage has dropped to a lower value because all of the flip-flops are toggling. As noted above, this situation occurs only in testing the SoC and is especially prevalent in multiple core SoCs that may run up to 400 clocks or more at one time. Test time is further increased when it is necessary to test multiple voltage levels. The voltage drop adversely affects test time and results.

Embodiments described below provide a method and apparatus for enabling the voltage and/or temperature sensors during DFT operation. Using these sensors provides a means to monitor both voltage and temperature as DFT testing is performed. Both the voltage and temperature sensors are used in normal operation to monitor the SoC for over-voltage and over-temperature conditions. A high temperature can cause the output voltage to drop. The drop adversely affects SoC operation and may limit the operations performed, and under severe conditions, may even shut down the SoC.

Various mechanisms may be used to measure the voltage drop. The voltage sensor incorporated into the SoC may be used to see the amount of voltage drop that occurs when multiple cores on the SoC are operating concurrently. The temperature sensors provide temperature readings that may be monitored as more cores operate. An SoC may have multiple temperature sensors, and they may be placed in key areas, depending on design needs and specification requirements.

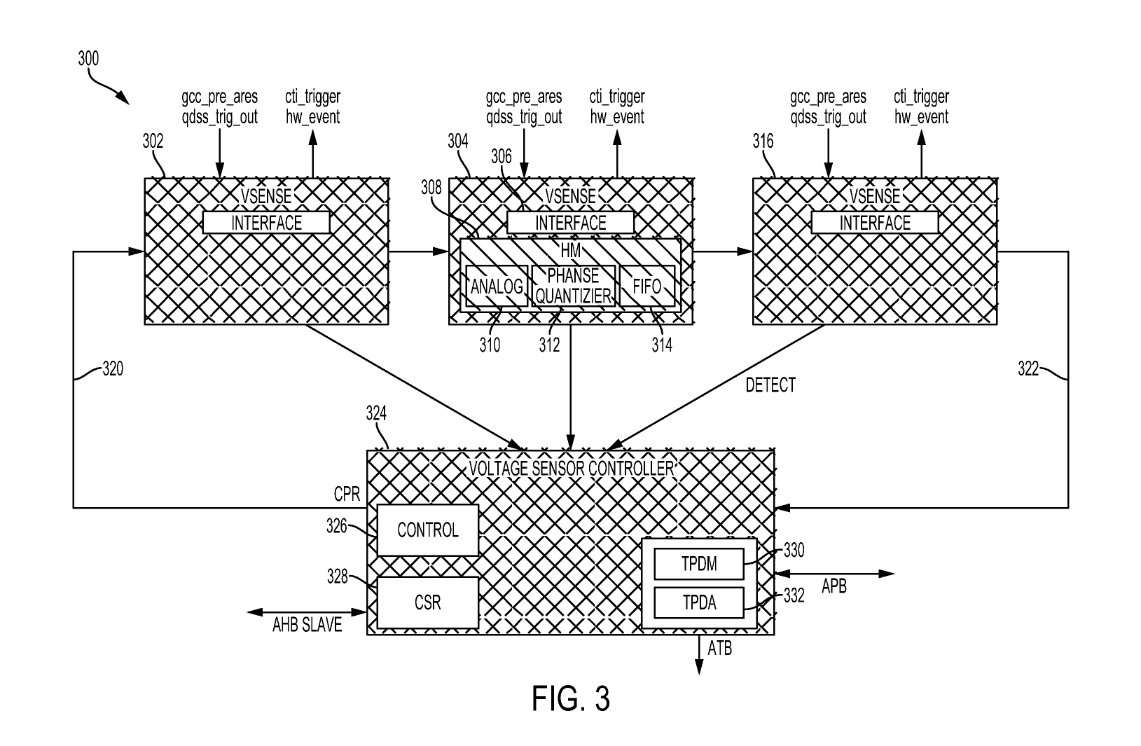

FIG. 3 depicts a voltage sensor for a multiple core SoC. The assembly 300 includes voltage sense modules 302, 304, and 316. Each voltage sensor may include an interface 306, a hardware module 308. The hardware module 308 may further contain analog element 310, a phase quantizer 312, and a first-in first-out device 314. The voltage sensing modules may interface with an output module 320 and also with a detect module 322. Each of the multiple voltage sensors 302, 304, and 316 provides an output to the voltage sensor controller 324. Voltage sensor controller 324 includes control logic 326, current sensor relay 328, telemetric power distribution module 330, and two phase decentralized adapter module 332.

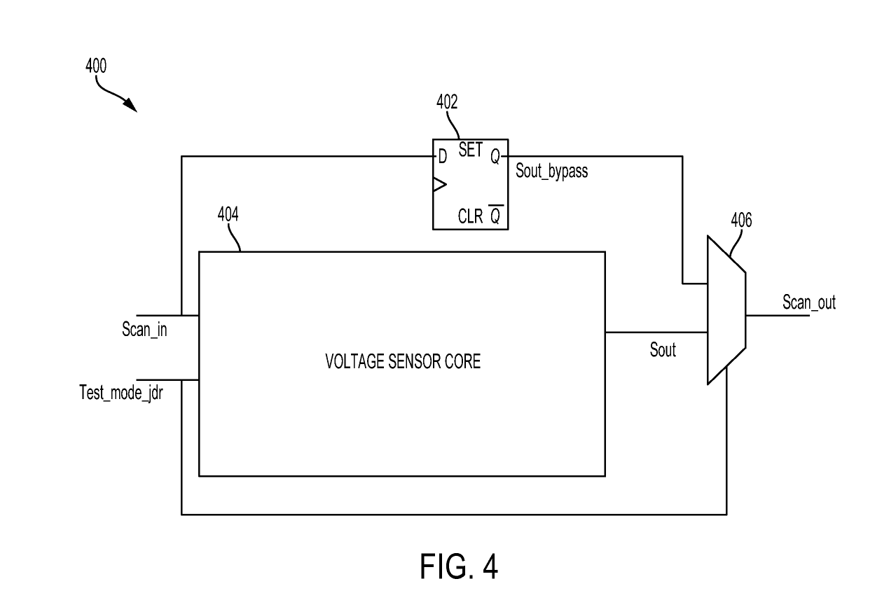

FIG. 4 is a block diagram of a voltage sensor used in embodiments described below. The assembly 400 includes a D flip-flop 402 which is connected to the scan in line. Voltage sensor core 404 is also connected to the scan in line, and is further connected to the test mode line in. D flip-flop 404 has the scan out bypass connection connected to 2:1 multiplexer 406. Voltage sensor core 404 has a scan out line providing input to multiplexer 406. Multiplexer 406 provides a connection to the test mode input line, and also provides a scan out signal.

An embodiment provides that the voltage and/or temperature sensors may be enabled during DFT mode testing. Either the voltage or the temperature sensors may be separately enabled, or both voltage and temperature sensors may be enabled. The selection may be determined based on the testing planned for the SoC or other device. Once the voltage and/or temperature sensors are enabled, the voltage sensor modules, which have a separate scan chain, are programmed using the JTAG driven register (JDR) bits. Either the separate scan chain or JDR bits may be used. A determination is then made of how many cores of the SoC may be run at one time. The temperature sensors measure the temperature on the chip, and this is used to determine how many cores may operate at the same time, while remaining within the operating temperature guidelines.

Voltage sensor assembly 400 may capture the maximum and minimum voltage levels on a power rail or bus during the shift and capture phase. Temperature readings may also be captured at this time. The temperature readings may be read directly from a temperature sensor or may be based on the voltage readings acquired in the capture phase. Based on the voltage sensor reading the optimum number of shift clocks to minimize voltage drop may be determined. The same voltage sensor readings may also be used to determine the optimum number of capture domains to realize efficient testing without undue or extreme temperature increases in the device or SoC being tested. The voltage sensor readings may also assist with yield analysis, where the functional vectors are mapped with the PDF vectors.

One controller may be used to measure the voltage drop across multiple cores of the SoC. This sensor may also be used when performing TDF testing. TDF testing uses the outside loop while the stuck at fault test uses the inside loop. These paths are also reflected in FIG. 4 Similar operations may be performed using the temperature sensors. Each voltage rail or bus may be tested using a different sensor, which allows for testing multiple voltage rails in parallel.

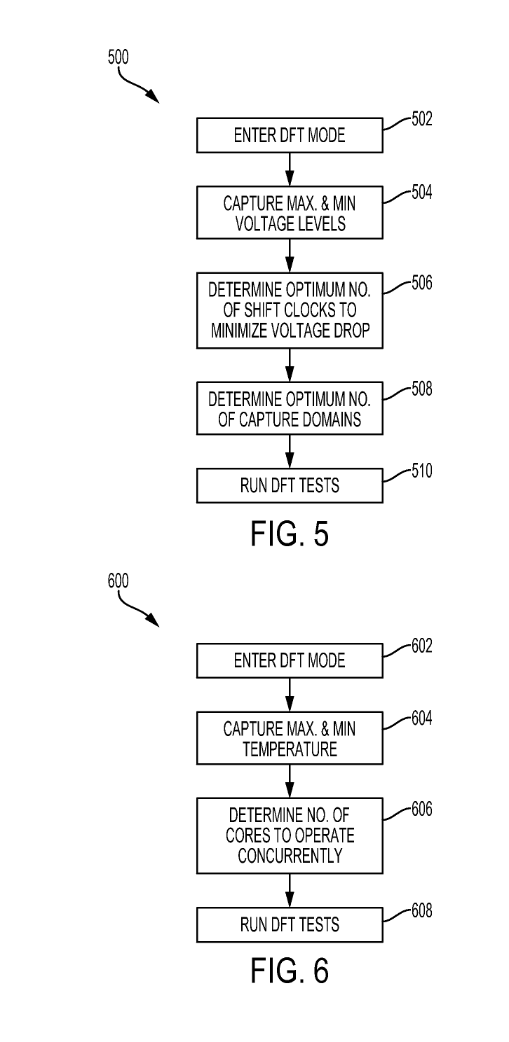

FIG. 5 is a flowchart of a method of testing voltage sensors for simultaneous at-speed capture. The method 500 begins when the DFT mode is entered in step 502. Multiple voltage sensors are used and each measures one voltage domain. The voltage controller measures the voltage drop across the multiple voltage domains. Once the measurements have been made, the optimum number of shift clocks that may be active at one time while still mainlining minimize voltage drop is determined in step 506. In step 508 a similar determination is made for the number of capture domains that can operate concurrently is determined Once the above determinations have been made, in step 510 the DFT tests are run.

FIG. 6 is a flowchart of a method of using temperature sensors to determine a number of cores on a SoC that may be tested simultaneously at speed during DFT testing. The method 600 begins when the DFT mode is entered. Maximum and minimum temperatures for each core may be determined and considered in determining the number of cores that may operate concurrently in step 606. In step 608 the DFT testing is performed using the number of simultaneously active cores determined using the temperature sensors.

The embodiments described above allow the number of test pads needed on the SoC or device to be reduced, as the testing is performed using the optimum shift frequency and phases between the test clocks. In addition, die cost may be reduced because test time and package costs are less. Fewer tests and fewer test-specific pins results in cost savings. Testing may also be helpful in debug testing in the post-silicon production process where test failures are examined Yield may also be improved, speed binning may be possible because of the temperature monitoring and voltage droop results may produce more accurate binning.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitter over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM EEPROM, CD-ROM or other optical disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A method of testing an electronic component, comprising:
entering a design-for-test (DFT) mode;
enabling at least one sensor to operate when the electronic component is in the DFT mode;
monitoring the at least one sensor output results; and
determining a number of cores or capture domains on the electronic component that may be tested simultaneously based on the at least one sensor output results.

2. The method of claim 1, wherein the at least one enabled sensor is a voltage sensor.

3. The method of claim 2, wherein monitoring the sensor output results captures maximum and minimum voltage levels for each capture domain.

4. The method of claim 3, further comprising determining an optimum number of shift clocks to minimize a voltage drop across the electronic component.

5. The method of claim 1, wherein the at least one enabled sensor is a temperature sensor.

6. The method of claim 5, wherein monitoring the at least one sensor output results captures a maximum and minimum temperature for each core.

7. The method of claim 6, further comprising determining a number of cores to operate simultaneously.

8. The method of claim 1, wherein enabling at least one sensor enables a voltage sensor and a temperature sensor.

9. The method of claim 8, wherein determining a number of capture domains or cores to be tested simultaneously is based on results from the multiple sensors.

10. The method of claim 9, wherein the multiple sensors include a voltage sensor and a temperature sensor.

11. An apparatus for testing an electronic component, comprising:
an electronic device having multiple cores and multiple capture domains;
test sensors on the electronic device in communication with the multiple cores and the multiple capture domains; and
an interface to a test fixture.

12. The apparatus of claim 11, further comprising multiple clocks in communication with the test sensors.

13. An apparatus for testing an electronic component, comprising:
means for entering a design-for-test (DFT) mode;
means for enabling at least one sensor to operate when the electronic component is in the DFT mode;
means for monitoring the at least one sensor output results; and
means for determining a number of cores or capture domains on the electronic component that may be tested simultaneously based on the at least one sensor output results.

14. The apparatus of claim 13, wherein the means for enabling at least one sensor enables a voltage sensor, a temperature sensor, or both the voltage and the temperature sensor.

15. The apparatus of claim 13, wherein the means for monitoring the at least one sensor output captures maximum and minimum voltage levels, maximum or minimum temperature readings, or both the maximum and minimum voltage levels and maximum and minimum temperature readings for each capture domain.

16. The apparatus of claim 13, wherein the means for determining a number of cores or capture domains on the electronic component that may be tested simultaneously bases the determination on a voltage reading, a temperature reading, or both the voltage reading and the temperature reading.

17. The apparatus of claim 13, wherein the means for determining the optimum number of shift clocks bases the determination on a voltage drop across the electronic component.

18. The apparatus of claim 13, wherein the means for determining the optimum number of shift clocks bases the determination on a maximum temperature on the electronic component.
